(19) United States
(12) Patent Application Publication
(10) Pub. No.: US 2008/0272395 A1
(43) Pub. Date: Nov. 6, 2008

(54) ENHANCED HOLE MOBILITY P-TYPE JFET AND FABRICATION METHOD THEREFOR

(75) Inventor: Srinivasa R. Banna, San Jose, CA (US)

Correspondence Address: PERKINS COIE LLP, P.O. BOX 1208, SEATTLE, WA, 98111-1208, US

(73) Assignee: DSM Solutions, Inc., Los Gatos, CA (US)

(21) Appl. No.: 12/114,140

(22) Filed: May 2, 2008

Related U.S. Application Data
(60) Provisional application No. 60/927,747, filed on May 3, 2007.

(51) Int. Cl. H01L 29/778; H01L 21/337

(52) U.S. Cl. 257/190; 257/256; 438/191; 257/E29.246; 257/E21.403

(57) ABSTRACT

Enhanced hole mobility p-type JFET and fabrication methods. A p-type junction field effect transistor including a substrate of n-type, a source region and a drain region formed in the substrate; wherein the source region and the drain region are p-type doped and at least one of the source region and the drain region is formed with silicon-germanium compound (Si₁₋ₓGeₓ), a p-type channel disposed between the source and the drain in the substrate; wherein compressive stress is induced in the p-type channel substantially along a channel length by the Si₁₋ₓGeₓ, and an n-type gate region within the p-type channel. The n-type gate region is electrically coupled to a gate contact that is operable to modulate a depletion width of the p-type channel.

### CROSS-REFERENCE TO RELATED APPLICATIONS

This application claims the benefit of priority under one or more of 35 U.S.C. 119 and 35 U.S.C. 120 and is related to U.S. Provisional Patent Application No. 601927,747 filed May 3, 2007 naming as inventors Srinivasa R. Banna and entitled Stressed P Channel Junction Field Effect Transistor, which application is hereby incorporated by reference.

### TECHNICAL FIELD

This invention relates generally to semiconductor devices, and, in particular, to p-type junction field-effect transistors with enhanced hole mobility.

### BACKGROUND

Speed of operation in switching transistors depends upon drain current since parasitic and load capacitances coupled to the drain need to be charged and discharged as switching occurs. This charging and discharging changes the voltage on these capacitors to switch transistors on and off. Therefore, larger drain currents can in many instances enable transistors to operate at higher frequencies.

In field-effect transistors (FETs), the drain current is generally proportional to the number of charge carriers and their carrier velocities of these carriers. Further, carrier velocity is proportional to the electric field and carrier mobility in the material of interest. By increasing the carrier mobility, drain current can be increased without having to increase the electric field (e.g., by applying a larger drain bias).

Carrier mobility depends upon the effective mass of a charge carrier, which is material specific. In general, the effective mass of a charge carrier (e.g., holes or electrons) in a particular material can be deduced from the amount of band bending (e.g., second derivative of the valence band edge or the conduction band edge with respect to k) of the valence band edge or conduction band edge in k-space.

Stress (e.g., compressive and/or tensile) induced in a semiconductor material affects material properties and energy levels as would be evident in the shape of the valence band and conduction band (plotted as energy vs. k) in k-space.

Stress (e.g., compressive and/or tensile) may changes the band banding of the conduction band edge and/or the valence band edge implying a higher or lower effective mass for electrons and/or holes, respectively. Therefore, appropriate types of stresses can be used to increase carrier mobility (e.g., for holes and/or electrons) in a semiconductor to increase transistor drive current, as may be visualized by the degree of change in band bending in the conduction and/or valence band edges between unstressed and stressed states.

### SUMMARY

Enhanced hole mobility JFET transistors and other semiconductor structures and devices and fabrication methods are provided.

One aspect there is provided a method of enhancing majority hole carrier mobility in a semiconductor device including, inducing compressive stress in a channel of the semiconductor device substantially along a length of the channel and/or inducing tensile stress in the channel substantially along a depth of the channel. The channel is p-type doped having holes as majority carriers. The compressive and/or tensile stresses can be induced by lattice mismatching surrounding material to the channel.

In one non-limiting embodiment, the semiconductor device is a junction field effect transistor (JFET). The compressive stress in the channel can be induced by silicon germanium compound (Si₁₋ₓGeₓ) in a source region and/or a drain region of the semiconductor device. In addition, the tensile stress in the channel is induced by Si₁₋ₓGeₓ in the source region and/or the drain region. The tensile stress is, in one embodiment, induced in the p-type channel substantially along a channel depth by the Si₁₋ₓGeₓ. The compressive stress can also be induced by a stressed nitride film deposited on a top surface of the semiconductor device, the stressed nitride film in contact with at least one of the source region and the drain region of the semiconductor device. Other embodiments may use a combination of the stress inducing methods and associated structures including the use of by silicon germanium compound (Si₁₋ₓGeₓ) in a source region and/or a drain region of the semiconductor device and the use of a stressed nitride film deposited on a top surface of the semiconductor device where the stressed nitride film in contact with at least one of the source region and the drain region of the semiconductor device.

In another aspect, there is provided a p-type junction field effect transistor, having, a substrate with an n-type well, a source region and a drain region formed in the substrate; wherein the source region and the drain region are p-type doped and at least one of the source region and the drain region is formed with silicon germanium compound (Si₁₋ₓGeₓ), a p-type channel disposed between the source and the drain in the substrate; wherein compressive stress is induced in the p-type channel substantially along a channel length by the Si₁₋ₓGeₓ, and/or an n-type gate region within the p-type channel. The n-type gate region is typically electrically coupled to a gate contact that is operable to modulate a depletion width of the p-type channel.

The gate contact can include polysilicon or metal. For the Si₁₋ₓGeₓ, x is typically at least 0.2 and in the range of about 0.2 to about 0.7, more usually in the range between 0.3 and 0.5, and in one non-limiting embodiment, substantially 0.4. Additionally, where x in Si₁₋ₓGeₓ may also be, substantially one of 0.2, 0.25, 0.3, 0.35, 0.45, 0.5, 0.55, 0.60, 0.65, 0.7 or any value or range between any two of these specific exemplary values.

One embodiment includes, a stressed nitride layer deposited over a top surface of the transistor and in contact with at least the source region and the drain region to further induce compressive stress in the p-type channel. The stressed nitride layer can be a contact etch stop layer comprising substantially of stressed silicon nitride. The p-type channel has bulk-mobility enhanced holes as majority carriers due to the compressive stress induced in the p-type channel.

One aspect of the present invention include, a p-type junction field effect transistor, having, a substrate with an n-type well, a source region and a drain region formed in the substrate; wherein the source region and the drain region are p-type doped, a p-type channel disposed between the source and the drain in the substrate, a stressed nitride layer deposited over a top surface of the transistor and in contact with at least the source region and the drain region to induce compressive stress in the p-type channel, and/or an n-type gate region within the p-type channel. The n-type gate region is electrically coupled to a gate contact that is operable to modulate a depletion width of the p-type channel. The p-type channel has bulk-mobility enhanced holes as majority carriers due to the compressive stress induced in the p-type channel.

In one embodiment, the stressed nitride layer is comprised substantially of a stressed silicon nitride layer.

One aspect of the present invention includes, a p-type junction field effect transistor, having, a substrate of n-type, a source region and a drain region formed in the substrate; wherein the source region and the drain region are p-type doped, a first trench and a second trench formed in the substrate, a p-type channel between the first and second trenches in the substrate, and/or an n-type gate region within the p-type channel. The n-type gate region is electrically coupled to a gate contact that is operable to modulate a depletion width of the p-type channel. The gate contact may be polysilicon or metal.

In one embodiment, the first and second trenches are formed with silicon germanium compound (Si₁₋ₓGeₓ). The Si₁₋ₓGeₓ may be epitaxially grown (eSiGe).

A further aspect of the present invention includes a method, of fabricating a reduced leakage current p-type junction field-effect transistor (pJFET), including forming a p-type channel region in a substrate, depositing a polysilicon layer on the channel region of the substrate, patterning the polysilicon layer according to a predetermined location for one or more of, a source region, a drain region, and a gate region, forming a first trench for the drain region and a second trench for the source region, epitaxially growing silicon-germanium compound in the first trench and the second trench, forming a gate contact, and/or forming an n-type gate region.

In one embodiment, the forming the gate contact, comprises, masking and/or etching the polysilicon layer. The gate contact can be masked off thus p-type impurities can be implanted into the first trench and second trench to form the source region and the drain region. In yet a further embodiment, stressed silicon nitride layer is optionally formed over a top surface of the pJFET and in contact with at least the source region and the drain region to induce compressive stress in the p-type channel.

In another aspect, there is provided a junction field effect transistor (JFET) comprising: a channel region electrically coupled to source and drain regions; and first and second trenches located on first and second opposite sides of the channel region and deeper than a back gate PN junction of the channel region; the first and second trenches filled with epitaxially grown silicon-germanium single crystal alloy.

Other aspects and features of the present invention will be apparent from the accompanying drawings and from the detailed description which follows.

### BRIEF DESCRIPTION OF THE DRAWINGS

FIG. 1 is a diagrammatic representation of a band diagram illustrating one example of the effect of stress on semiconductor material properties as evidenced by the change in the shape of the conduction band edge and/or the valence band edge.

FIG. 2A illustrates an example of a cross sectional view of a p-type junction field-effect transistor (pJFET) with enhanced hole mobility having p-type silicon-germanium compound (Si₁₋ₓGeₓ) regions as the source and drain, according to one embodiment.

FIG. 2B illustrates another example of a cross sectional view of a p-type junction field-effect transistor (pJFET) with enhanced hole mobility having p-type Si₁₋ₓGeₓ regions as the source and drain, according to one embodiment.

FIG. 3 illustrates yet another example of a cross sectional view of a p-type junction field-effect transistor (PJFET) with enhanced hole mobility having p-type Si₁₋ₓGeₓ regions as the source and drain, according to one embodiment.

FIG. 4A illustrates a further example of a cross sectional view of a p-type junction field-effect transistor (pJFET) with enhanced hole mobility having p-type Si₁₋ₓGeₓ regions in addition to the source and drain, according to one embodiment.

FIG. 4B illustrates a yet further example of a cross sectional view of a p-type junction field-effect transistor (pJFET) with enhanced hole mobility having p-type Si₁₋ₓGeₓ regions in addition to the source and drain, according to one embodiment.

FIG. 5 illustrates an example process flow for fabricating an enhanced hole mobility p-type JFET with p-type doped Si₁₋ₓGeₓ source and drain regions, according to one embodiment.

FIG. 6 illustrates an example process flow for fabricating an enhanced hole mobility p-type JFET with p-type doped Si₁₋ₓGeₓ regions between the gate and source and drain regions, respectively, according to one embodiment.

### DETAILED DESCRIPTION

The following description and drawings are illustrative and are not to be construed as limiting. Numerous specific details are described to provide a thorough understanding of the disclosure and invention. However, in certain instances, well-known or conventional details are not described in order to avoid obscuring the description.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

Embodiments of the present invention include enhanced hole mobility p-type JFETs and fabrication methods thereof.

Although exemplary non-limiting embodiments of the present invention are described with example reference to junction field effect transistors (JFET), and has particular significance, applicability, and advantages, the application of the novel aspect of the invention is not limited as such to JFETs. Applications of the principles of hole mobility enhancement disclosed herein to other types of devices of additional or same materials systems (e.g., Si, Ge, GaAs, other III-V systems, etc.) are contemplated and are considered to be within the scope of this disclosure, including but not limited to, metal-semiconductor field effect transistors (MESFETs), Ge/Si FETs, and/or any other JFET device whereby charge transport is performed by majority hole carriers.

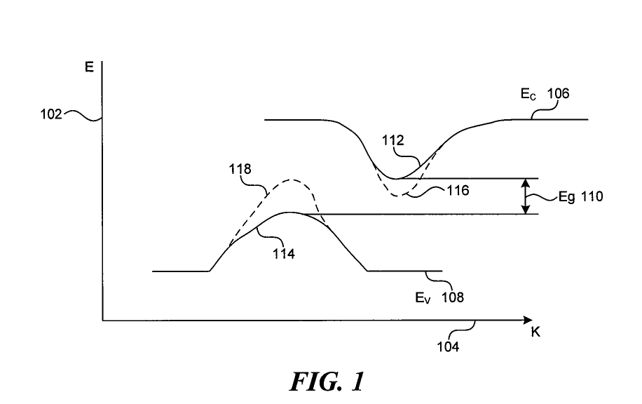

FIG. 1 is a diagrammatic representation of an example band diagram 100 illustrating one example of the effect of stress on semiconductor material properties as evidenced by the change in the shape of the conduction band edge 106 and/or the valence band edge 108.

Curve 114 depicts the shape of the valance band edge 108 when the semiconductor material is unstressed. Curve 112 depicts the shape conduction band edge 106 when the semiconductor material is unstressed.

In some instances, inducing stress in the semiconductor material (e.g., bulk, 2D, or 1D) causes the shape of the conduction band edge and/or the valence band edge to change. For example, the shape of the band edges may shift to the shapes illustrated by curves 116 and 118. Alteration of the shape of these bands causes the band bending, or, the second derivative of the valence band and conduction band with respect to k to change. Since the degree of band bending of the conduction band edge and the valence band edge is qualitatively related to the effective mass of electrons and holes, respectively, a change in the amount of band bending also reflects a change in carrier mobility.

By inducing stress (e.g., compressive and/or tensile stress) in a particular type of semiconductor material and structure, the effective mass of the charge carriers can be decreased as evident by the increase in band bending of the conduction band edge (for electrons) and/or the valence band edge (for holes) in the stressed versus unstressed states.

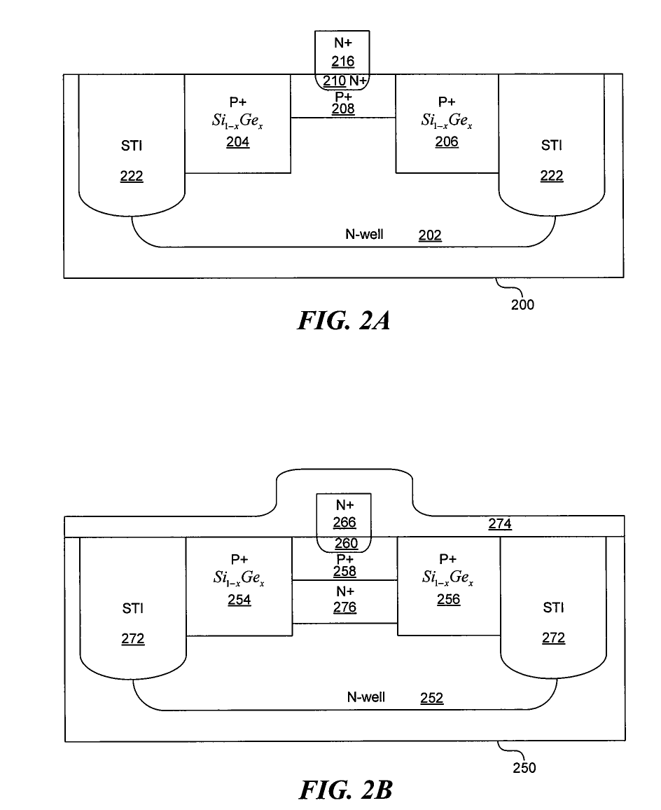

FIG. 2A illustrates an example of a cross sectional view of a p-type junction field-effect transistor (pJFET) 200 with enhanced hole mobility having p-type eSiGe regions as the source region 204 and the drain region 206, according to one embodiment.

The pJFET 200 may be fabricated from any known and/or convenient methods on an n-type substrate. The substrate is typically but not limited to silicon. The substrate could also be silicon-on-insulator (SOI). The pJFET 200 includes heavily doped polysilicon including, a source contact, a gate contact 216, and a drain contact. The contacts may be approximately 50 nm thick. The pJFET 200 may include an n-well region 202 in which the source region 204 and drain region 206 are formed. In some instances, the gate contact 216 has insulating sidewall spacers (not shown) on each side which may include a layer of silicon dioxide and in some instances, an additional layer of silicon nitride.

Additionally, the channel region 208 (e.g., p-channel) may be disposed between the source region 204 and the drain region 206 in the n-well 202. The depth of the channel is typically, but not limited to between about 50 Angstroms and about 500 Angstroms, more usually between about 250 Angstroms and about 350 Angstroms, and in one non-limiting exemplary embodiment, about 300 Angstroms. Typical value is 300 angstroms. The channel depth may be, for example, but is not limited to 30 Å, 40 Å, 50 Å, 60 Å, 75 Å, 100 Å, 150 Å, 175 Å, 200 Å, 250 Å, 300 Å, 350 Å, 400 Å, 450 Å, or 500 Å.

In some instances, the active area of the pJFET 200 is defined by Shallow Trench Isolation (STI) trenches 222. Typically the STI trenches 222 form an active area over which the source, drain and gate contacts are formed. STI trenches can also form another active area (not shown) which is electrically coupled to the main active area over which a back gate contact is formed.

In one embodiment, the source region 204 and/or the drain region 206 is formed from p-type doping silicon germanium compound (Si₁₋ₓGeₓ)regions. The Si₁₋ₓGeₓ may be epitaxially grown (eSiGe). For example, two trenches may be formed on two ends of the channel for epitaxial Si₁₋ₓGeₓ growth. In general, the two trenches for Si₁₋ₓGeₓ (or more simply SiGe) growth is deeper than the channel back gate PN junction (e.g., the junction between p-channel 208 and n-well 202) and shallower than the STIs 222. The SiGe trench depth may typically be 2 times to 3 times the channel length. For example, if the channel length is about 50 nm (Leff=50 nm) then the SiGe trenches may typically be in the range of at least between about 500 Angstrom deep, and more typically between about 1000 Angstrom and about 1500 Angstrom deep. This trench depth may not specifically depend on a channel back gate PN junction location.

Crystalline germanium has a greater lattice constant than silicon. The mismatch in distance between atoms in a crystalline germanium compared to crystalline silicon is approximately 4% to 6%.

Therefore, lattice mismatch of the Si₁₋ₓGeₓ source and drain regions with the silicon substrate and channel regions induces compressive stress along the length of the channel 208 which enhances hole mobility in the pJFET 200. In addition, tensile stress is generated from the Si₁₋ₓGeₓ regions along the depth of the channel 208. The composition of germanium in the Si₁₋ₓGeₓ can be any fraction sufficient to induce stress in the adjacent material (e.g. Si). In one embodiment, the composition of germanium is approximately 40% (or, x˜0.4). In alternative embodiments, the composition of germanium may be, but is not limited to, 20%, 25%, 30%, 35%, 45%, 50%, 55%, 60% (e.g., x˜0.2, 0.25, 0.3, 0.35, 0.45, 0.5, 0.55, 0.6, 065, 0.7). Non-limiting embodiments provide for the Si₁₋ₓGeₓ, x to be typically in the range of about 0.2 to about 0.7, more usually in the range between 0.3 and 0.5, and in one non-limiting embodiment, substantially 0.4. Additionally, where x in Si₁₋ₓGeₓ may also be, substantially one of 0.2, 0.25, 0.3, 0.35, 0.45, 0.5, 0.55, 0.6, 0.65, or 0.7, or any value or range between any two of these specific exemplary values.

One embodiment of the enhanced hole mobility pJFET includes a punch-through layer disposed under the channel. A further embodiment of the enhanced hole mobility pJFET includes stressed nitride layer deposited on the top surface of the device. Both embodiments are illustrated with further reference to FIG. 2B.

In the example silicon-based pJFET shown in FIG. 2A, compressive stress along the channel length and/or tensile stress along the channel depth decreases the effective mass of holes in silicon resulting in a corresponding mobility increase.

However, the novel aspects of the present embodiments are not limited to enhancing hole mobilities in silicon based transistors and extend to other material systems where the mobility of the majority carrier (e.g., hole or electron) is enhanced by inducing an appropriate amount of stress (e.g., compressive and/or tensile) along the suitable dimensions of the transistor. The techniques discussed above are generally applicable to any JFET where current conducts by movement of majority carriers and are considered to be within the scope of the novel aspects of the embodiments. For example, similar techniques may be utilized to enhance electron mobility in an nJFET.

Methods for operating a JFET (nJFET and/or PJFET) and the related principles of operations (e.g., in the enhancement mode and the depletion mode) are well known to those skilled in the art and are not further described here. In one embodiment, the JFET operates in the enhancement mode, or otherwise referred to as the normally-off mode. The novel semiconductor devices and structures operating in these modes have enhanced operating characteristics and performance over conventional devices and structures, including by way of example, but not limitation, enhanced mobility, in particular, enhanced hole mobility, and other implications thereof.

FIG. 2B illustrates another example of a cross sectional view of a p-type junction field-effect transistor (pJFET) 250 with enhanced hole mobility having p-type Si₁₋ₓGeₓ regions as the source region 254 and the drain region 256 having a punch through region 276, according to one embodiment.

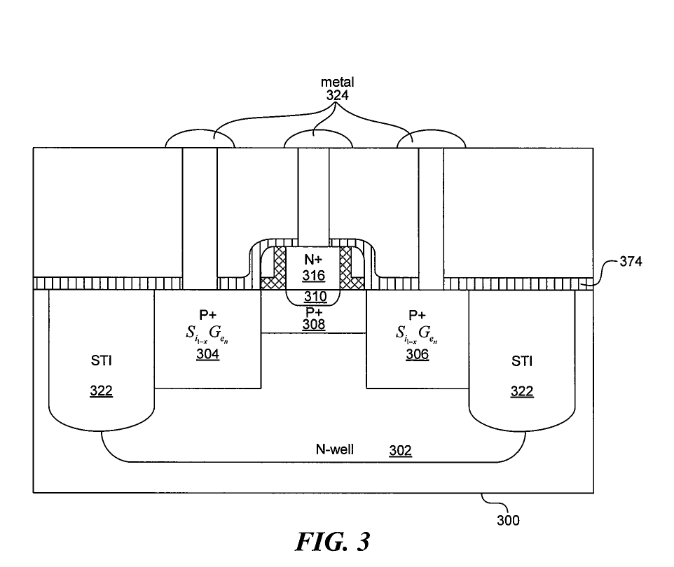

The pJFET 250 includes STIs 272, a source region 254 and/or a drain region 256 formed from Si₁₋ₓGeₓ, a p-type channel 258, and n-type gate region 260. The pJFET 250 also includes a source contact, a drain contact, and a gate contact 266. In one embodiment, the source, drain, and/or gate contacts are highly doped polysilicon. In addition, the source, drain, and/or gate contacts may be metallic, as illustrated with further reference to FIG. 3.

One embodiment of an enhanced hole mobility pJFET includes an n-type punch-through region 276 implanted below the p-type channel 258 in the n-well 252. In general, the punch-through region 276 is heavily doped n-type (N+). The doping concentration of the punch-through region 276 can be coordinated with the electrical characteristics (e.g., doping density, doping profile, and/or channel depth, etc.) of the p-type channel to obtain desired transistor switching characteristics.

For example, the doping profiles may be coordinated such that the channel region 258 is pinched off at zero gate bias such that the device is in enhancement mode. In one embodiment, the source region 254 and/or the drain region 256 formed from Si₁₋ₓGeₓ is deeper than the junction between the punch-through region 274 and the substrate (or the n-well 252) and shallower than the depth of the STIs 272.

A further embodiment of the enhanced hole mobility pJFET includes a stressed nitride layer (e.g., layer 274) deposited over a top surface of the pJFET 250. The stressed nitride layer 274 can be, for example, stressed nitride layer which is a contact etch stop layer that comprises substantially of silicon nitride.

The stressed nitride layer 274 is generally in contact with at least the source 254 and drain 256 regions of the pJFET 250 to induce compressive stress in the p-type channel 258. The stressed nitride layer 274 can be used to induce compressive stress in the p-type channel 258 in addition to the stress induced by the source region 254 and/or the drain region 256 formed from Si₁₋ₓGeₓ to further enhance the mobility of holes in the channel.

In some embodiments, other silicon-oxide and silicon-nitride based dielectrics in addition to silicon nitride may also be able to induce same or similar types and magnitude of stress on the channel 258 and may be used are contemplated and are considered to be within the novel scope of the techniques herein described. Silicon dioxide for example, may be used to produce stress but to a lesser degree. Therefore, small dimension devices and structures, such as devices having dimensions that are less than 45 nm, and even more advantageously devices having dimensions smaller than 32 nm, and even more advantageously devices having dimensions of about 22 nm or smaller may take advantage of SiO2 as a compressive stress film.

Note that the stressed nitride layer 274 may be used in conjunction with or independent of the source region 254 and/or the drain region 256 formed from Si₁₋ₓGeₓ for enhancing hole mobility in pJFETs. One embodiment of an enhanced hole mobility pJFET (not shown) includes a stressed nitride layer without source and/or drain regions formed from silicon-germanium compound, for example, with or without an N+ punch-through layer (such as the N+ punch-through layer 276 of the example pJFET 250 of FIG. 2B).

Non-limiting embodiments may use a combination of the stress inducing methods and associated structures including the use of by silicon germanium compound (Si₁₋ₓGeₓ) in a source region and/or a drain region of the semiconductor device and the use of a stressed nitride film deposited on a top surface of the semiconductor device where the stressed nitride film in contact with at least one of the source region and the drain region of the semiconductor device.

FIG. 3 illustrates yet another example of a cross sectional view of a p-type junction field-effect transistor (pJFET) 300 with enhanced hole mobility having p-type Si₁₋ₓGeₓ regions as the source 304 and drain 306, according to one embodiment.

The pJFET 300 includes STIs 322, a source region 304 and/or a drain region 306 formed from Si₁₋ₓGeₓ, a p-type channel 308, and n-type gate region 318. The pJFET 300 also includes metallic source, drain, and gate contacts 324. One embodiment includes a stressed nitride layer 374 formed on the top surface of the pJFET 300 to further induce compressive stress on the channel 308, which further enhances the hole mobility in the p-type channel 308. In further embodiments, the pJFET 300 includes an n-type punch through region (not illustrated) implanted below the p-type channel region 308.

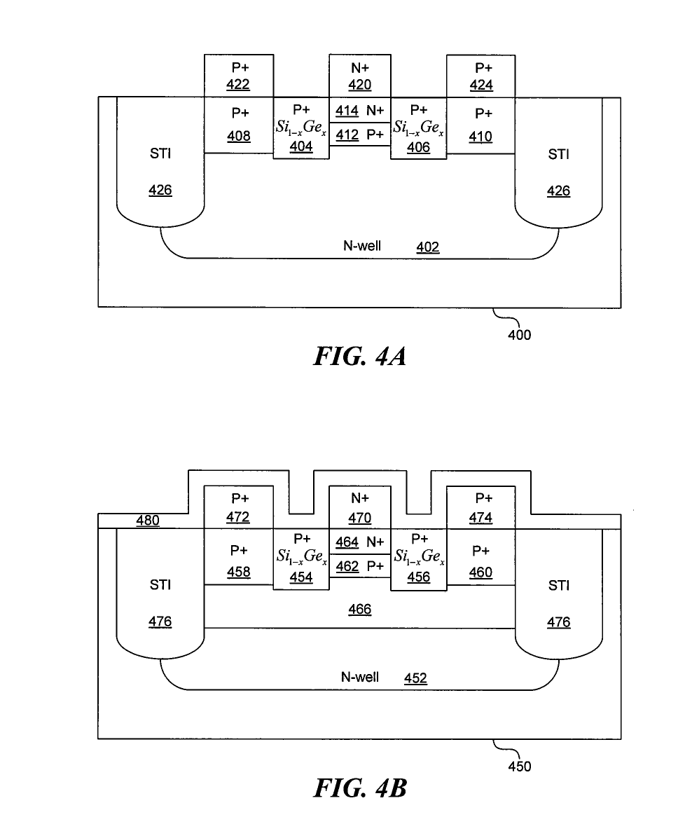

FIG. 4A illustrates a further example of a cross sectional view of a p-type junction field-effect transistor (pJFET) 400 with enhanced hole mobility having p-type Si₁₋ₓGeₓ regions 404 and 406 in addition to the source region 408 and drain region 410, according to one embodiment.

The pJFET 400 includes STIs 426, a source region 408, a drain region 410, a p-type channel 412, and n-type gate region 414. The pJFET 400 also includes source 422, drain 424, and gate contacts 420. The source region 408 and/or the drain region 410 are p-type doped and generally highly doped (e.g., P+ doping). One embodiment of the enhanced hole mobility pJFET 400 includes a first trench 404 disposed in the substrate at one end of the channel 412 in contact with the source region 408. The pJFET may further include a second trench 406 disposed in the substrate at the other end of the channel 412 in contact with the drain region 410. In one embodiment, at least one of the first trench 404 and the second trench 406 is formed from Si₁₋ₓGeₓ.

The Si₁₋ₓGeₓ trenches 404 an 406 at the two ends of the channel 412 provide the same and/or otherwise similar benefits in the operation of pJFET 400 as that described with reference to FIG. 2A and FIG. 2B by enhancing the mobility of the carrier holes in the p-type channel 412 via stress induced in the channel 412. The composition of germanium in the compound (Si₁₋ₓGeₓ) can be any fraction sufficient to induce stress in adjacent material (e.g. Si). In one embodiment, the composition of germanium is approximately 40% (or, x˜0.4). In addition, the composition of germanium may be, but is not limited to, 20%, 25%, 30%, 35%, 45%, 50%, 55%, 60% (e.g., x˜0.2, 0.25, 0.3, 0.35, 0.45, 0.5, 0.55, 0.6, 0.65, 0.7). Additional advantages of having Si₁₋ₓGeₓ trenches separate from the source region 408 and the drain region 410 may include, in non-limiting examples, of the FIG. 4A structure versus the structures in FIG. 2, include but are not limited to the following: (a) the regular source/drain (S/D) polysilicon helps better pattern the gate polysilicon, (b) permits forming shallow junction by dopant diffusion through polysilicon, (c) better junction scaling and robust silicide formation, (d) a flatter wafer surface at contact lithograph during the process, and (e) any combination of these.

The Si₁₋ₓGeₓ trenches 404 and 406 are, in most instances, further doped with p-type impurities to form link regions linking the channel region 412 to the source region 408 and the drain region 410. One embodiment of an enhanced hole mobility pJFET further includes a punch-through region disposed below the channel region, as illustrated with reference to FIG. 4B.

Further, note that although polysilicon source, drain, and gate contacts are illustrated in the example of FIG. 4B, metal contacts such as illustrated in FIG. 2A and FIG. 2B may also or alternatively be used. In addition, a stressed nitride layer (not illustrated) may be deposited on the top surface of pJFET 400 to enhance the stress induced in the channel by the Si₁₋ₓGeₓ trenches 404 and 406. Stressed nitride, or similar variants thereof, can further enhance the hole mobility in the channel 412, for example, with further reference to the description of FIG. 2B.

FIG. 4B illustrates a yet further example of a cross sectional view of a p-type junction field-effect transistor (pJFET) 450 with enhanced hole mobility having p-type Si₁₋ₓGeₓ regions 454 and 456 in addition to the source 458 and drain 460 having a punch-through region 466, according to one embodiment.

The pJFET 450 includes STIs 476, a source region 458, a drain region 460, a p-type channel 462, and n-type gate region 464. The pJFET 450 also includes source 472, drain 474, and gate contacts 470. The source region 458 and/or the drain region 460 are p-type doped and generally highly doped (e.g., P+ doping).

The pJFET 450 further includes p-type doped Si₁₋ₓGeₓ trenches 454 an 456 at the two ends of the channel 462 and are in contact with the source region 458 and the drain region 460, respectively. The pJFET 450 further includes an n-type punch through layer 466 disposed below the p-type channel 460. Generally, the Si₁₋ₓGeₓ trenches 454 and 456 are formed deeper than the P-N junction between the channel region 462 and the punch through layer 466 and shallower than the STIs 476.

A further embodiment of the enhanced hole mobility pJFET includes a stressed nitride layer (e.g., layer 480) deposited over a top surface of the pJFET 450. The stressed nitride layer 480 can be, for example, stressed nitride layer which is a contact etch stop layer that comprises substantially of silicon nitride.

The stressed nitride layer 480 is generally in contact with at least the source 472 and drain 474 contacts of the pJFET 450 to induce compressive stress in the p-type channel 462. The stressed nitride layer 480 can be used to induce compressive stress in the p-type channel 462 in addition to the stress induced by the region 454 and/or the region 456 formed from Si₁₋ₓGeₓ to further enhance the mobility of holes in the channel.

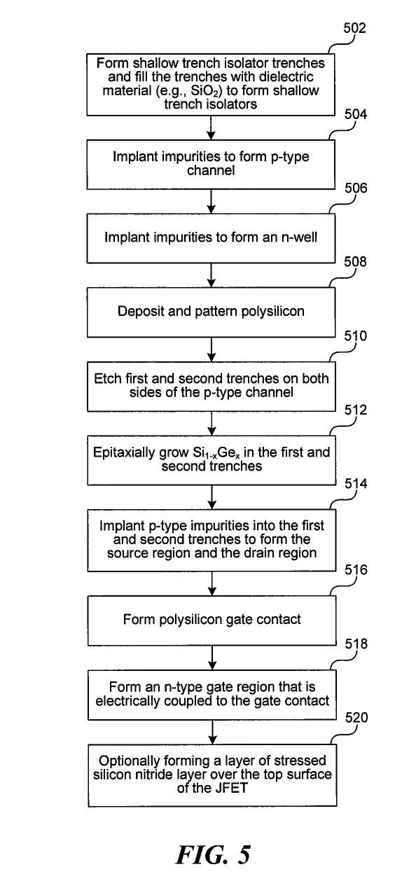

FIG. 5 illustrates an example process flow for fabricating an enhanced hole mobility p-type JFET with p-type doped silicon germanium compound (Si₁₋ₓGeₓ) source and drain regions, according to one embodiment.

In process 502, shallow trench isolator (STI) trenches are formed and deposited with dielectric material (e.g., SiO₂). The shallow trench isolators typically define active areas for transistors, and in this instance, for JFETS and in particular, pJFETs. STIs can be formed according to any known and/or convenient manner.

In process 504, the channel region is implanted. The channel region may be formed according to any known and/or convenient manner, for example, by dopant diffusion and/or ion implantation. For an nJFET or pJFET, the channel depth is generally in the range of about 2 nm to about 100 nm, more usually in the range from about 5 nm to about 50 nm, even more usually in the range from about 20 nm to about 40 nm, and in one particular non-limiting embodiment substantially 30 nm., although other depths may be implemented, without deviating from the novel aspects and features of the embodiments. In particular, for a pJFET, p-type dopants are used for channel formation. By way of example but not limitation, in a silicon based device, materials with five valence electrons such as phosphorus and/or arsenic can be used to for n-type doping and materials with three valence electrons such as boron and/or gallium can be used for p-type doping.

In addition, a punch-through implant region is optionally formed below the channel region. The punch-through region is generally of opposite conductivity as the channel region. Therefore, for a pJFET, the punch-through implant region is typically doped n-type and frequently heavily doped (e.g., N+).

In process 506, a well is implanted in the substrate. The well implant can be formed according to any known and/or convenient manner. In particular, an n-well is generally formed for a pJFET encompassing the channel region. If a punch-through region was formed, the n-well region also encompasses the punch-through region.

In process 508, polysilicon is deposited on the device. The polysilicon may be doped using any suitable technique, such as diffusion, ion implantation, or in-situ doping. For example, in an nJFET, the source-drain polysilicon may be selectively doped using n-type impurities. When a pJFET is constructed the source-drain polysilicon may be selectively doped using p-type impurities. The polysilicon layer may be approximately 50 nm. but other thicknesses may be used.

In addition, in process 508, the polysilicon layer is also patterned. The polysilicon may be defined via any selective etching process (e.g., plasma etch, chemical etch, dry etch, wet etch, etc.) to form the source, gate, and/or drain contacts. The etching process may involve forming a mask to expose appropriate portions of the polysilicon.

In process 510, first and second trenches on both sides of the p-type channel are formed by etching. The gate contact is generally masked off with an etch mask while etching the trenches. The gate contact and/or the optional spacer can self-align the edges of the trenches with the outer edges of the gate contact or the spacer. The trenches are typically deeper than the P-N junction (the junction between the p-type channel and the n-well, or the junction between the p-type channel and the N+ punch-through region for a pJFET) and shallower than bottoms of STI trenches. The trenches are optionally cleansed with hydrofluoric acid (HF) or any other suitable solvent to remove oxidations (e.g., silicon dioxide) from the walls inside the trenches. The wafer may be further stored in inert atmosphere such as hydrogen with little or no oxygen after the HF etch to prevent any oxidation of the trenches (e.g., SiO₂ formation).

In process 512, silicon-germanium compound (Si₁₋ₓGeₓ) is grown in the first and second trenches. The Si₁₋ₓGeₓ is, in one embodiment formed by performing epitaxial growth (eSiGe) by any known and/or convenient manner. In general, the epitaxial growth process is performing low-pressure chemical vapor deposition (LPCVD) in an environment with inert atmosphere which has little or no oxygen.

In process 5148, the source and drain regions are formed by implanting impurities into the first and second Si₁₋ₓGeₓ trench regions. For a pJFET, p-type impurities are used. The source and drain regions may be formed according to any known and/or convenient manners, for example, by the diffusion of dopants through a corresponding polysilicon depositions. For an n-type JFET or a p-type JFET, the source/drain junction depth is may typically be in the range from about 20 nm to about 100 nm, more usually in the range from about 30 nm to about 75 nm, even more usually in the range from substantially 40 nm to substantially 50 nm, and in one non-limiting embodiment, substantially 50 nm, although other implantation depths may be implemented. In general, the source and drain depth is deeper than the P-N junction (e.g., the junction between the p-type channel and the n-well, or the p-type channel and the N+ punch through region, for a pJFET).

In process 516, the polysilicon gate contact is formed by the performing the appropriate masking and doping processes. For example, the regions outside the polysilicon gate contact are masked and n-type impurities are used to dope the gate contact N+. Alternatively, the gate contact can be doped during an N+ implant when the source and drain region implants are being performed. The polysilicon is then etched to form the gate contact.

In process 518, a gate region is formed. For an n-type JFET or p-type JFET, the gate junction depth is typically in the range between about 2 nm and 30 nm, more usually in the range between about 5 nm and 15 nm, and in one particular non-limiting embodiment, substantially 10 nm, although other implantation depths may be implemented. The n-type gate region can be formed by thermally annealing implanted impurities in the gate contact and driving-in impurities from polysilicon diffusing into underlying channel to form the gate region. In an alternative embodiment, the thermal drive-in after the N+ implant when the source and drain region implants are being performed. The source/drain/gate length is generally 60 nm each however alternate dimensions may be implemented. In one embodiment, the source/drain/gate region doping density is approximately 1 e²⁰-2 e²⁰/cm³.

Dielectric sidewall spacers are optionally formed about the polysilicon gate for mitigating high fields between the gate and the channel. For pJFET or nJFET devices, each sidewall spacer is generally approximately anywhere between 0-15 nm along the length of the device. The sidewall spacers may include two layers. More particularly, the sidewall spacers include a first layer of silicon dioxide immediately adjacent to the polysilicon followed by a layer of silicon nitride. In one embodiment, the sidewall spacers include a single layer sidewall material of, for example, silicon dioxide.

In process 520, according to one embodiment, a layer of stressed nitride layer (e.g., silicon nitride), is formed over the top surface of the JFET. The stressed nitride layer can be deposited by any known and/or convenient manner. In one embodiment, the stressed nitride layer is compressed silicon nitride contact etch stop layer (CESL). This compressive layer is generally built up in layers by altering pressure, temperature and time parameters during deposition of multiple layers to build stress into the final composite multilayer structure. The stressed nitride layer is generally formed over at least the source and drain contacts and induces compressive stress along the length of the JFET channel thus reducing hole effective mass resulting in enhanced hole mobility.

From here, the remainder of JFET is formed using suitable fabrication techniques. For example, at least depositing a metallic material over one or more of the source region, the drain region, and gate region to form one or more ohmic contacts, and forming the metal interconnects, including, depositing interlayer dielectrics, etching contact holes, depositing barrier metals, etc. Silicide may be optionally deposited over the polysilicon gate region to decrease the contact and series resistance.

The order of the processes described can be alternated. Additional or less steps may be included. For example, the order in which the n-well, punch-through implant and channel region and gate regions are formed can be varied as suitable. In a further example, the gate surface contact can be doped when the polycrystalline silicon is etched with a mask and implant step after the polysilicon etch, or with an implant of N-type impurities before the polysilicon etch.

In addition, although a process for polysilicon contacts is described, it is acknowledged that metal contacts may be used for one or more of the gate contact, drain contact, and/or source contact in an enhanced hole mobility pJFET and is considered to be within the novel techniques herein described. The example process described in association with FIG. 5 can be suitably modified for incorporation of deposition of metal contacts in lieu of polysilicon contacts and is also considered to be within the novel aspects of the techniques herein described.

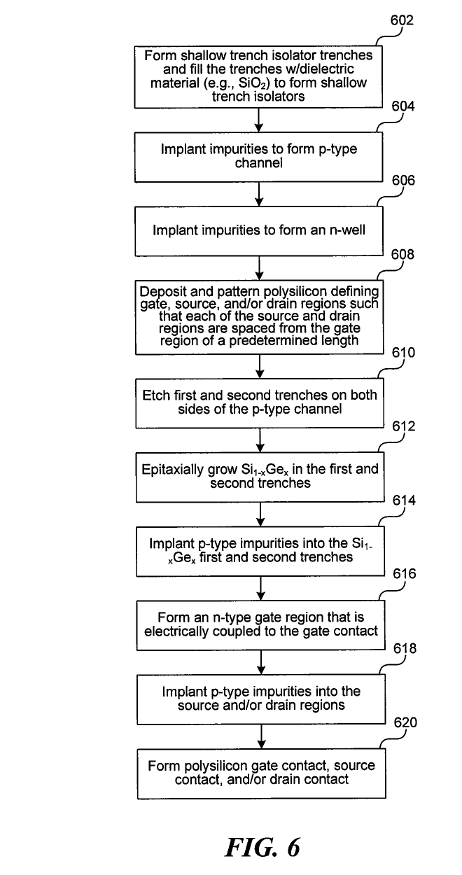

FIG. 6 illustrates an example process flow for fabricating an enhanced hole mobility p-type JFET with p-type doped Si₁₋ₓGeₓ regions between the gate and source and drain regions, respectively, according to one embodiment.

Processes 602-608 can be illustrated with the same or otherwise similar description associated with the corresponding processes of the process flow in the example of FIG. 5. Note that in process 608, the polysilicon is deposited and patterned such that each of the source and drain regions are spaced from the gate region of a predetermined length. The spacing is determined such that a first trench for Si₁₋ₓGeₓ formation is located between one end of the channel and the source region and a second trench for Si₁₋ₓGeₓ formation is located between the other end of the channel and the drain region.

In process 610, the first and second trenches on both sides of the p-type channel are formed by etching. In process 612, silicon-germanium compound (Si₁₋ₓGeₓ) is grown in the first and second trenches. In process 614, p-type impurities are implanted into the Si₁₋ₓGeₓ first and second trenches. In process 616, an n-type gate region electrically coupled to the gate contact is formed. In process 618, p-type impurities are implanted into the source and/or drain regions. In process 620, polysilicon gate contact, source contact, and drain contacts are formed. The corresponding processes are described in detail with references to the description of FIG. 5.

The above detailed description of embodiments of the disclosure is not intended to be exhaustive or to limit the teachings to the precise form disclosed above. While specific embodiments of, and examples for, the disclosure are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times. Further any specific numbers noted herein are only examples: alternative implementations may employ differing values or ranges.

The teachings of the disclosure provided herein can be applied to other methods, devices, and/or systems, not necessarily to those described above. The elements and acts of the various embodiments described above can be combined to provide further embodiments.

What is claimed is:

1. A method of enhancing majority hole carrier mobility in a semiconductor device, the method comprising:
inducing compressive stress in a channel of the semiconductor device substantially along a length of the channel; wherein the channel is p-type doped having holes as majority carriers; and
inducing tensile stress in the channel substantially along a depth of the channel; wherein the compressive or tensile stresses are induced by lattice mismatching surrounding material to the channel.

2. The method of claim 1, wherein, the semiconductor device is a junction field effect transistor (JFET).

3. The method of claim 1, wherein the compressive stress in the channel is induced by silicon-germanium compound (Si₁₋ₓGeₓ) in one or more of a source region and a drain region of the semiconductor device.

4. The method of claim 1, wherein the tensile stress perpendicular to the channel is induced by Si₁₋ₓGeₓ in one or more of a source region and a drain region of the semiconductor device.

5. The method of claim 4, wherein x is at least 0.2.

6. The method of claim 1, wherein the compressive stress is induced by a stressed nitride film deposited on a top surface of the semiconductor device, the stressed nitride film in contact with at least one of the source region and the drain region of the semiconductor device.

7. A p-type junction field effect transistor, the transistor comprising:
a substrate with an n-type well;
a source region and a drain region formed in the substrate; wherein the source region and the drain region are p-type doped and at least one of the source region and the drain region is formed with silicon-germanium compound (Si₁₋ₓGeₓ);
a p-type channel disposed between the source and the drain in the substrate; wherein compressive stress is induced in the p-type channel substantially along a channel length by the Si₁₋ₓGeₓ; and
an n-type gate region within the p-type channel; wherein the n-type gate region is electrically coupled to a gate contact that is operable to modulate a depletion width of the p-type channel.

8. The transistor of claim 7, wherein the gate contact comprises polysilicon or metal.

9. The transistor of claim 7, wherein tensile stress is induced in the p-type channel substantially along a channel depth by the Si₁₋ₓGeₓ.

10. The transistor of claim 7, wherein x is at least 0.2.

11. The transistor of claim 7, wherein x is between the range of 0.2-0.7.

12. The transistor of claim 7, further comprising, a stressed nitride layer deposited over a top surface of the transistor and in contact with at least the source region and the drain region to further induce compressive stress in the p-type channel.

13. The transistor of claim 12, wherein the stressed nitride layer is a contact etch stop layer comprising substantially stressed silicon nitride.

14. The transistor of claim 7, wherein the Si₁₋ₓGeₓ is epitaxially grown (eSiGe).

15. The transistor of claim 7, wherein, the p-type channel has bulk-mobility enhanced holes as majority carriers due to the compressive stress induced in the p-type channel.

16. The transistor of claim 7, further comprising, an n-type punch-through region adjacent and under the p-type channel region.

17. The transistor of claim 16, further comprising, an n-type well region in which the punch-through region is formed.

18. A p-type junction field effect transistor, the transistor comprising:
a substrate with an n-type well;
a source region and a drain region formed in the substrate; wherein the source region and the drain region are p-type doped;
a p-type channel disposed between the source and the drain in the substrate;
a stressed nitride layer deposited over a top surface of the transistor and in contact with at least the source region and the drain region to induce compressive stress in the p-type channel; and
an n-type gate region within the p-type channel; wherein the n-type gate region is electrically coupled to a gate contact that is operable to modulate a depletion width of the p-type channel.

19. The transistor of claim 18, wherein, the p-type channel has bulk-mobility enhanced holes as majority carriers due to the compressive stress induced in the p-type channel.

20. The transistor of claim 18, wherein, the stressed nitride layer comprises substantially of stressed silicon nitride layer.

21. A p-type junction field effect transistor, the transistor comprising:
a substrate with an n-type well;
a source region and a drain region formed in the substrate; wherein the source region and the drain region are p-type doped;
a first trench and a second trench formed in the substrate;
wherein the first trench is in contact with the source region and the second trench is in contact with the drain region;
wherein the first and second trenches are formed with silicon-germanium compound (Si₁₋ₓGeₓ);
a p-type channel between the first and second trenches in the substrate; wherein compressive stress is induced in the p-type channel substantially along a channel length by the Si₁₋ₓGeₓ; and
an n-type gate region within the p-type channel; wherein the n-type gate region is electrically coupled to a gate contact that is operable to modulate a depletion width of the p-type channel.

22. The transistor of claim 21, wherein the gate contact comprises polysilicon or metal.

23. The transistor of claim 21, wherein tensile stress is induced in the p-type channel substantially along a channel depth by the Si₁₋ₓGeₓ.

24. The transistor of claim 21, wherein x is at least 0.2.

25. A method of fabricating a p-type junction field-effect transistor (pJFET) with reduced leakage current, the method, comprising:
forming a p-type channel region in a substrate;
depositing a polysilicon layer on the channel region of the substrate; patterning the polysilicon layer according to a predetermined location for one or more of, a source region, a drain region, and a gate region;
forming a first trench for the drain region and a second trench for the source region;
epitaxially growing silicon-germanium compound in the first trench and the second trench
forming a gate contact; and
forming an n-type gate region.

26. The method of claim 25, wherein the first and second trenches are etched to be deeper than the p-type channel region.

27. The method of claim 25, wherein, the forming the gate contact, comprises,
masking the polysilicon layer;
implanting the polysilicon layer with n-type impurities; and
etching the polysilicon layer to form the gate contact.

28. The method of claim 27, further comprising, performing a thermal drive in to diffuse the n-type impurities from the gate contact into the underlying p-type channel region to form the gate region.

29. The method of claim 25, wherein the p-type channel region and the gate region are formed by ion implantation.

30. The method of claim 25, further comprises, masking off the gate contact and implanting p-type impurities into the first trench and second trench to form the source region and the drain region.

31. The method of claim 25, further comprises, forming a stressed silicon nitride layer over a top surface of the pJFET and in contact with at least the source region and the drain region to induce compressive stress in the p-type channel.

32. A junction field effect transistor (JFET) comprising:
a channel region electrically coupled to source and drain regions; and
first and second trenches located on first and second opposite sides of said channel region and deeper than a back gate PN junction of said channel region;
said first and second trenches filled with epitaxially grown silicon-germanium single crystal alloy.

33. The JFET of claim 32, wherein the silicon-germanium single crystal alloy takes the form Si₁₋ₓGeₓ, where x is at least 0.2.

34. The JFET of claim 33, wherein:
said junction field effect transistor has polysilicon source, drain and gate surface contacts with gaps between said surface contacts filled with dielectric material,
said surface contacts in electrical contact with source, drain and gate regions, respectively, of said JFET and having metal silicide formed on top thereof and having photolithographically determined distances between said gate surface contact and said source and drain surface contacts.
